(19) United States
(12) Patent Application Publication
(10) Pub. No.: US 2006/0180845 A1
(43) Pub. Date: Aug. 17, 2006

(54) Memory device with silicon rich silicon oxide layer and method of manufacturing the same

(75) Inventors: Young-Kwan Cha, Yongin-si (KR); In-Kyeong Yoo, Suwon-si (KR); Soo-Hwan Jeong, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/350,867

(22) Filed: Feb. 10, 2006

(30) Foreign Application Priority Data
Feb. 12, 2005 (KR) 10-2005-0011733

(51) Int. Cl. H01L 21/8238; H01L 29/76; H01L 21/326

(52) U.S. Cl. 257/314; 438/467; 438/201

(57) ABSTRACT

A memory device with a silicon rich oxide layer and a method of manufacturing the same are provided. The memory device with a silicon rich oxide layer may include a semiconductor substrate, source/drain regions formed on the semiconductor substrate, and a gate structure formed on the semiconductor substrate. The gate structure may contact with the source/drain regions and may include a silicon oxide layer with a silicon content greater than that of a silicon oxide layer (SiO₂).

### PRIORITY STATEMENT

This application claims the benefit of Korean Patent Application No. 10-2005-0011733, filed on Feb. 12, 2005, in the Korean Intellectual Property Office, the disclosure of which is incorporated herein in its entirety by reference.

### BACKGROUND OF THE INVENTION

1. Field of the Invention

Example embodiments of the present invention relate to a memory device with a silicon rich silicon oxide layer and a method of manufacturing the same, and more particularly, to a non-volatile memory device including a tunneling oxide layer formed with a multi layer structure of a dielectric layer having a different energy bandgap, and a method of manufacturing the same.

2. Description of the Related Art

Memory devices may be classified as volatile memory and non-volatile memory. Examples of volatile memory are a dynamic random access memory (DRAM) and a static random access memory (SRAM). Volatile memory may access data when power remains applied, but data disappears when power is removed. Non-volatile memory can retain data even if power is removed. A representative non-volatile memory is a flash memory.

FIG. 1 is a sectional view of a conventional non-volatile memory, specifically a floating gate type flash memory.

Referring to FIG. 1, a first dopant region 11a and a second dopant region 11b, which are doped with dopant, may be formed on a semiconductor substrate 10. A channel region may be formed between the first dopant region 11a and the second dopant region 11b in the semiconductor substrate 10. A gate structure may be formed on the channel region which the first dopant region 11a and the second dopant region 11b contact. The gate structure may include a tunneling oxide layer 12, a floating gate 13, a blocking oxide layer 14, and a gate electrode layer 15 formed of a conductive material, which may be sequentially formed on the channel region. The tunneling oxide layer 12 may be formed of a dielectric material (e.g., a silicon oxide layer) and the floating gate 13 may be formed of a polysilicon.

In the conventional non-volatile memory illustrated in FIG. 1, the floating gate 13 may be formed of poly silicon or silicon nitride (Si₃N₄) so as to hold a trap site serving as a charge trap region for storing charge, or a silicon nanodot may be formed. However, the process of manufacturing the memory device with the above structure may require a high temperature thermal treatment. In the case of a semiconductor-oxide-nitride-oxide-semiconductor (SONOS) memory, it may be difficult to reduce the thickness of the tunneling oxide layer 12 below 3 nm because a bandgap distribution of a trap site may not be uniform. Although retention may be improved as the tunneling oxide layer 12 is thicker, data programming and erasing properties may deteriorate, due to the trap sites that are naturally generated in the tunneling oxide layer 12 by a voltage applied during data write/read operations.

### SUMMARY OF THE INVENTION

Example embodiments of the present invention provide a memory device with improved data retention property and/or data programming/erasing speed, and a method of manufacturing the same.

According to an example embodiment of the present invention, there is provided a memory device including a semiconductor substrate further including a source region and a drain region formed thereon and a gate structure formed on the semiconductor substrate contacting the source region and the drain region, the gate structure including a silicon-oxide layer having a silicon content greater than that of silicon dioxide (SiO₂).

In an example embodiment, the gate structure may include a tunneling oxide layer, a floating gate, and/or a control gate.

In an example embodiment, the floating gate may be formed of SiOₓ (1.0<x<1.6).

In an example embodiment, the tunneling oxide layer may be formed of SiO₂.

According to another example embodiment of the present invention, there is provided a method of manufacturing a memory device forming a gate structure on a semiconductor substrate, the gate structure including a floating gate with a silicon content greater than that of SiO₂, etching both sides of the gate structure to expose both surfaces of the semiconductor substrate, and forming a source region and a drain region by doping both surfaces of the exposed semiconductor substrate.

In an example embodiment, forming the gate structure may include forming a tunneling oxide layer on the semiconductor substrate and injecting a silane gas (SiH₄) and an oxygen gas (O₂) on the tunneling oxide layer to form a floating gate with a silicon oxide layer, of which a silicon content is greater than that of SiO₂.

In an example embodiment, a flow ratio of the silane gas (SiH₄) and the oxygen gas (O₂) may range from 1.43:1 to 1.57:1.

### BRIEF DESCRIPTION OF THE DRAWINGS

The above and other features and advantages of example embodiments of the present invention will become more apparent by describing in detail exemplary embodiments thereof with reference to the attached drawings in which:

FIG. 1 is a plan view of a conventional flash memory;

FIG. 2 is a plan view of a memory device with a silicon rich silicon oxide layer according to an example embodiment of the present invention;

FIGS. 3A through 3F are plan views illustrating a method of manufacturing a memory device with a silicon rich silicon oxide layer according to an example embodiment of the present invention;

FIG. 4 is a TEM photograph captured after forming a silicon rich silicon oxide layer according to an example embodiment of the present invention;

FIG. 5A is a graph illustrating a C-V curve in a MOS capacitor structure with a silicon rich silicon oxide layer according to an example embodiment of the present invention; and

FIG. 5B is a graph illustrating a retention property, at 250° C., of a memory device with a silicon rich silicon oxide layer according to an example embodiment of the present invention.

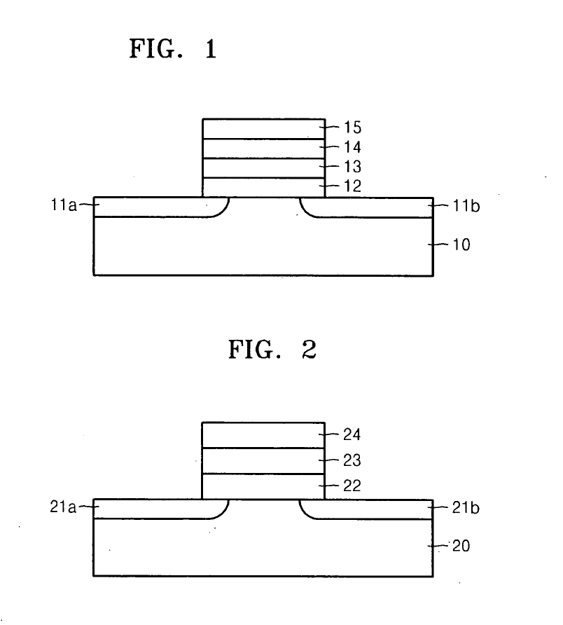

### DETAILED DESCRIPTION OF EXAMPLE EMBODIMENTS OF THE PRESENT INVENTION

The present invention is described more fully hereinafter with reference to the accompanying drawings, in which example embodiments of the present invention are shown. The present invention may, however, be embodied in many different forms and should not be construed as limited to the embodiments set forth herein. Rather, these example embodiments are provided so that this disclosure will be thorough and complete, and will fully convey the scope of the present invention to those skilled in the art. In the drawings, the sizes and/or relative sizes of layers and/or regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A memory device with a silicon rich silicon oxide layer and a method of manufacturing the same according to an example embodiment of the present invention will now be described with reference to the accompanying drawings.

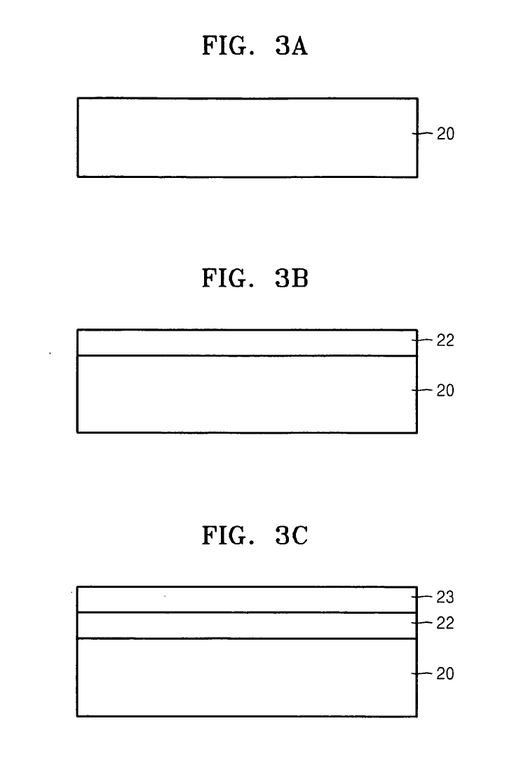

FIG. 2 is a plan view of a memory device with a silicon rich silicon oxide layer according to an example embodiment of the present invention. Referring to FIG. 2, a first dopant region 21a and a second dopant region 21b may be formed on a semiconductor substrate 20 and a gate structure may be formed on the semiconductor substrate 20 that the first dopant region 21a and the second dopant region 21b contact with. The gate structure may include a tunneling oxide layer 22, a silicon rich silicon oxide layer 23, and/or a control gate 24.

Any substrate used in a manufacturing process of a memory device can be used as the semiconductor substrate 20. The tunneling oxide layer 22 may be formed of SiO₂. The tunneling oxide layer 22 may also be omitted. The silicon rich silicon oxide layer 23 may be formed of SiOₓ, where x is in the range of 1.0 to 1.6. That is, the silicon rich silicon oxide layer 23 may have a higher silicon content ratio than that of the tunneling oxide layer 22 formed under the silicon rich silicon oxide layer 23 or a higher silicon content ratio than SiO₂. The control gate 24 may be formed of any conductive material used in a manufacturing process of a flash memory.

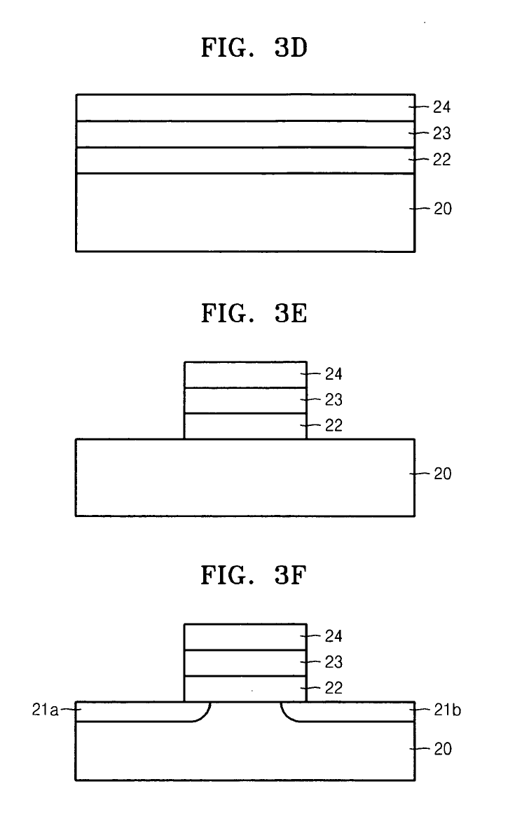

A method of manufacturing a memory device with a silicon rich silicon oxide layer according to an example embodiment of the present invention will now be described in detail. FIGS. 3A through 3F are plan views illustrating sequential procedures of manufacturing a memory device with a silicon rich silicon oxide layer according to an example embodiment of the present invention.

Referring to FIG. 3A, a semiconductor substrate 20 is prepared. Any substrate used in a manufacturing process of a memory device can be used as the semiconductor substrate 20. A silicon substrate is widely used as the semiconductor substrate 20.

Referring to FIG. 3B, a tunneling oxide layer 22 may be formed or coated on the semiconductor substrate 20. The tunneling oxide layer 22 may be formed of a silicon oxide (SiO₂). The tunneling oxide layer 22 may be formed or coated having a thickness of 3 nm or less.

Referring to FIG. 3C, the silicon rich silicon oxide layer 23 may be formed or coated on the tunneling oxide layer 22. In an example embodiment, a flow ratio of silane gas (SiH₄) and/or oxygen gas (O₂) may be controlled in the range of approximately 1.43 to 1.57 in a reaction chamber so as to deposit the silicon rich oxide layer 23. For example, the silicon rich silicon oxide layer 23 may be deposited with a silane flow of 1.0 sccm and an oxygen flow of 0.7 sccm. A conventional manufacturing apparatus for a memory device may be used to manufacture the memory device with the silicon rich silicon oxide layer 23 according to example embodiments of the present invention because the silicon rich silicon oxide layer 23 may be formed of a material similar or equal to that of the tunneling oxide layer 22 and only a flow ratio of supply gases injected into the chamber needs to be controlled.

Referring to FIG. 3D, a control gate 24 may be formed or coated on the silicon rich silicon oxide layer 23. The control gate 24 may be made of any conventional conductive material.

Referring to FIG. 3E, one or more sides of the tunneling oxide layer 22, the silicon rich silicon oxide layer 23, and/or the control gate 24 may be removed by an etching process, thereby exposing side surfaces of the semiconductor substrate 20.

Referring to FIG. 3F, the exposed side surfaces of the semiconductor substrate 20 may be doped with a dopant and a thermal treatment may be performed to activate the dopant. In this manner, the memory device is completed.

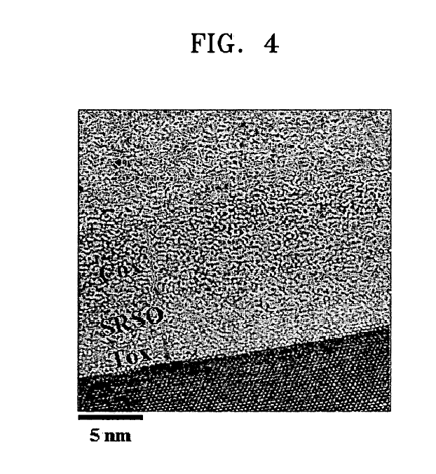

FIG. 4 is a TEM photograph captured after forming the silicon rich silicon oxide layer according to an example embodiment of the present invention. Referring to FIG. 4, a region indicated by SRSO represents the silicon rich silicon oxide layer having a thickness of about 4 nm, and a region indicated by Tox represents the tunneling oxide layer 22 formed of SiO₂ having a thickness of about 2 nm. If a silicon dot is formed, only a portion of the SRSO region will be shown distinctively, but the SRSO region of FIG. 4 is more uniformly formed of a single layer.

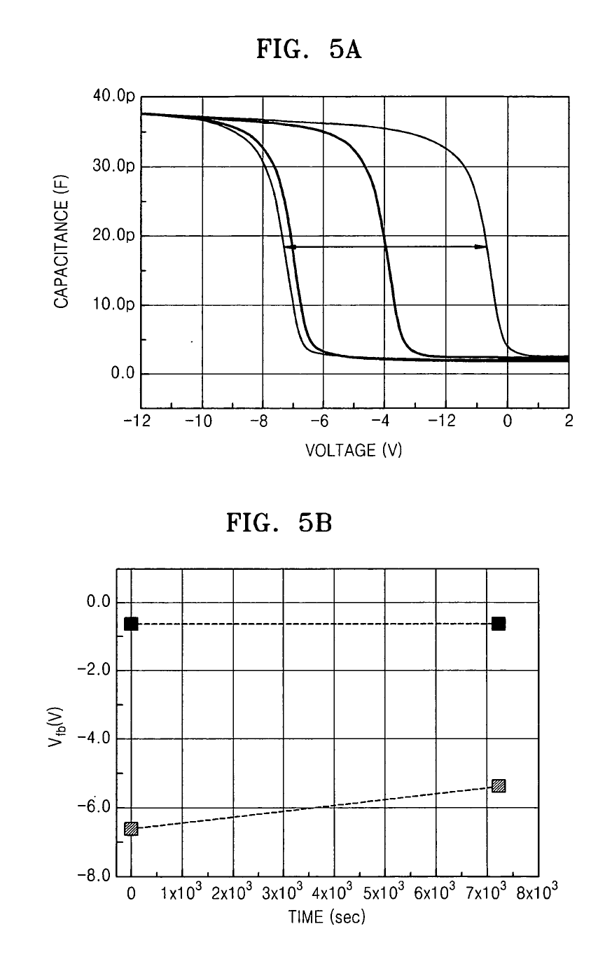

FIGS. 5A and 5B are graphs illustrating a memory property of the memory device with the silicon rich silicon oxide layer according to an example embodiment of the present invention.

The graph of FIG. 5A represents capacitance as a function of an applied voltage. When the applied voltage changes, a window region is shown on both sides centering on −4 V. Consequently, a charge trap site may be formed within the silicon rich silicon oxide layer 23.

FIG. 5B is a graph illustrating a change of a flat band voltage when charges are injected into the capacitor structure with the silicon rich silicon oxide layer at 10V and −10 V and then a thermal treatment is performed at 250° C. for two hours. It is known that a retention property is maintained for ten years at room temperature when a thermal treatment is performed at 250° C. for two hours. Referring to FIG. 5B, when a thermal treatment is performed at 250° C. for two hours, a flat band voltage difference of above 4 V is maintained, thereby improving the retention property.

According to example embodiments of the present invention, the floating gate may be formed of a silicon oxide layer with a silicon content greater than that of a typical silicon oxide layer (SiO₂). Therefore, the floating gate may have a more uniform composition as a whole and include a charge trap site. Also, the tunneling oxide layer formed under the floating gate may be formed with a thickness less than 3 nm and the resulting memory device may still have sufficient retention properties. Further, because the memory device may be manufactured using a conventional apparatus, the manufacturing process may be simplified. Still further, a time-consuming high temperature thermal treatment for a silicon dot is not required.

Although example embodiments of the present invention have been described above in conjunction with more silicon rich than SiO₂, other silicon oxides may also be the basis for determining silicon richness. For example, in other example embodiments, the silicon rich silicon oxide layer 23 may have a higher silicon content ratio than SiO₃ or SiO₄ or another silicon oxide.

Similarly, the teachings of example embodiments of the present invention may be applied to elements other than Si, for example, other Group IV elements, for example, Ge or C, or any other elements.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A memory device comprising:
a semiconductor substrate including a source region and a drain region formed thereon; and
a gate structure formed on the semiconductor substrate contacting the source region and the drain region, the gate structure including a silicon oxide layer having a silicon content greater than that of silicon dioxide (SiO₂).

2. The memory device of claim 1, wherein the silicon oxide layer acts as a floating gate, and the gate structure further includes a tunneling oxide layer and a control gate.

3. The memory device of claim 2, wherein the floating gate is formed of SiOₓ (1.0<x<1.6).

4. The memory device of claim 2, wherein the tunneling oxide layer is formed of SiO₂.

5. A method of manufacturing a memory device comprising:
forming a gate structure on a semiconductor substrate, the gate structure including a floating gate with a silicon content greater than that of SiO₂;
etching both sides of the gate structure to expose both surfaces of the semiconductor substrate; and
forming a source region and a drain region by doping both surfaces of the exposed semiconductor substrate.

6. The method of claim 5, wherein forming the gate structure comprises:
forming a tunneling oxide layer on the semiconductor substrate; and
injecting a silane gas (SiH₄) and an oxygen gas (O₂) on the tunneling oxide layer to form the floating gate as a silicon oxide layer, having a silicon content greater than that of SiO₂.

7. The method of claim 6, wherein a flow ratio of the silane gas (SiH₄) and the oxygen gas (O₂) ranges from 1.43:1 to 1.57:1.

8. The method of claim 7, wherein the floating gate is formed of SiOₓ (1.0<x<1.6).

9. The method of claim 5, wherein the gate structure includes a tunneling oxide layer, the floating gate, and a control gate.

10. A method of manufacturing the memory device of claim 1, the method comprising:
forming the gate structure on the semiconductor substrate, the gate structure including a floating gate with a silicon content greater than that of SiO₂;
etching both sides of the gate structure to expose both surfaces of the semiconductor substrate; and
forming the source region and the drain region by doping both surfaces of the exposed semiconductor substrate.
